(19) United States
(12) Patent Application Publication
(10) Pub. No.: US 2007/0145604 A1
(43) Pub. Date: Jun. 28, 2007

(54) CHIP STRUCTURE AND CHIP MANUFACTURING PROCESS

(75) Inventors: Chin-Li Kao, Penghu County (TW); Tong-Hong Wang, Selangor D. E. (MY); Yi-Shao Lai, Taipei County (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/610,319

(22) Filed: Dec. 13, 2006

(30) Foreign Application Priority Data
Dec. 22, 2005 (TW) 94145775

(51) Int. Cl. H01L 23/48; H01L 23/52; H01L 29/40

(52) U.S. Cl. 257/779

(57) ABSTRACT

A chip manufacturing process is disclosed. A wafer having a passivation layer and at least one bonding pad is provided. The surface of the bonding pad is exposed to a first opening of the passivation layer. A first metal layer is formed on the bonding pad exposed by the first opening. A photoresist having a second opening and a photoresist block disposed in the second opening is formed on the first metal layer. The first metal layer corresponding to the second opening has a first surface, and the first metal layer corresponding to the photoresist block has a second surface. A second metal layer is formed on the first surface, and the photoresist block is removed to expose the second surface. A UBM layer is formed on the second metal layer and the second surface of the first metal layer. Finally, a conductive bump is formed on the UBM layer.

### CROSS-REFERENCE TO RELATED APPLICATION

This application claims the priority benefit of Taiwan application serial no. 94145775, filed Dec. 22, 2005. All disclosure of the Taiwan application is incorporated herein by reference.

### BACKGROUND OF THE INVENTION

1. Field of the Invention

The present invention relates to a chip structure and a chip manufacturing process, and more particularly to a conductive structure on bonding pads and a manufacturing process thereof.

2. Description of Related Art

In semiconductor industry, the production of integrated circuits (IC) mainly includes three stages: wafer manufacturing, IC manufacturing, and IC package. Dies are produced through the steps of wafer manufacturing, circuit designing, circuit manufacturing, wafer sawing, and so on; each die formed by wafer sawing is electrically connected to an external carrier through the bonding pads on the die, and the dies are packaged, so as to prevent the dies from being influenced by humidity, heat, and noise.

In order to connect the dies and the carrier, wires and/or conductive bumps are usually used as a medium of the connection. Flip chip interconnect technology involves forming conductive bumps on the bonding pads of the dies, and respectively connecting the conductive bumps on the bonding pads to the contacts on the carrier, such that the chip can be electrically connected to the carrier through the conductive bumps.

FIG. 1 is a schematic sectional view of a conventional chip structure. Referring to FIG. 1, the chip structure 100 has a plurality of bonding pads 110 (only one is shown in FIG. 1). In addition, in order to avoid the chip structure 100 from being affected by external impurity or mechanical damage, a passivation layer 104 is formed on an active surface 102 of the chip structure 100. The passivation layer 104 has a plurality of openings 106 (only one is shown in FIG. 1) to expose the bonding pads 110, and a bump manufacturing process is performed on the surfaces of the bonding pads 110.

Referring to FIG. 1, through the above bump manufacturing process, an under bump metallurgic (UBM) layer 120 and a conductive bump 130 are formed on the bonding pads 110, so as to serve as conductive structures for electrically and structurally connecting the chip structure 100 to a carrier (not shown), wherein the UBM layer 120 is disposed between the bonding pads 110 and the conductive bump 130, so as to enhance the bonding between the bonding pads 110 and the conductive bump 130.

It should be noted that the UBM layer 120 is formed on the surface of the bonding pads 110 and the surrounding surface of the openings 106 in a manner of step coverage. Therefore, when the operating speed of the chip structure 100 increases, a large amount of current flows through the bonding pads 110 and flows to the UBM layer 120 at a turning angle 108 larger than or equal to 90 degrees, and thus the current will be extremely crowded (the density of the current increases at the turning angle 108) when passing through the turning angle 108, and result in electromigration phenomenon of metal atoms at the turning angle 108. As such, the metal atoms of the UBM layer 120 will be gradually lost due to electromigration, and thus an open circuit between the bonding pads 110 and the UBM layer 120 occurs, which further influences the lifetime of the chip.

### SUMMARY OF THE INVENTION

The present invention is directed to a chip structure and a chip manufacturing process capable of reducing or eliminating the problem of open circuit between the bonding pads and the UBM layer caused due to electromigration.

The present invention provides a chip structure, which comprises a chip, at least one bonding pad, a passivation layer, a metal layer, a UBM layer, and a conductive bump. The chip has an active surface, and the bonding pad is disposed on the active surface. The passivation layer is covered on the active surface, wherein the passivation layer has an opening, and the opening exposes an upper surface of the bonding pad. In addition, the metal layer is formed on the bonding pad in the opening, the UBM layer is disposed on the metal layer but not covered on the passivation layer, and the conductive bump is formed on the UBM layer.

In an embodiment of the present invention, the metal layer comprises a first metal layer and a second metal layer, wherein the first metal layer is disposed, for example, on the bonding pad, and the second metal layer is, for example, an annular structure and is disposed on a part of the surface of the first metal layer.

In an embodiment of the present invention, the first metal layer and the bonding pad are of the same material.

In an embodiment of the present invention, the material of the first metal layer and the second metal layer comprises, for example, Al or Ti.

In an embodiment of the present invention, the material of the UBM layer is, for example, one selected from a group consisting of Ni, Cu, Ti, and an alloy thereof.

In an embodiment of the present invention, the material of the conductive bump comprises, for example, Sn or Au.

The present invention further provides a chip manufacturing process, which comprises the following steps. First, a wafer is provided, wherein the wafer has a passivation layer and at least one bonding pad, and an upper surface of the bonding pad is exposed to a first opening of the passivation layer. Next, a first metal layer is formed on the upper surface of the bonding pad exposed to the first opening. Next, a photoresist having a second opening and a photoresist block is formed on the first metal layer, wherein the photoresist block is disposed in the second opening, the first metal layer corresponding to the second opening has a first surface, and the first metal layer corresponding to the photoresist block has a second surface. Then, a second metal layer is formed on the first surface, and the photoresist block is removed to expose the second surface. After that, a UBM layer is formed on the surface of the second metal layer and the second surface of the first metal layer. Thereafter, a conductive bump is formed on the UBM layer.

In an embodiment of the present invention, the first metal layer is formed by, for example, a sputtering/evaporation process.

In an embodiment of the present invention, the material of the first metal layer comprises, for example, Al or Ti.

In an embodiment of the present invention, the second metal layer is formed by, for example, an electroplating process.

In an embodiment of the present invention, the material of the second metal layer comprises, for example, Al or Ti.

In an embodiment of the present invention, the process of forming the conductive bump includes, for example, printing or electroplating.

In an embodiment of the present invention, after forming the conductive bump, the photoresist is removed.

The present invention further provides a chip structure, which is similar to the above-mentioned chip structure, except for an annular metal layer is used to replace the aforementioned metal layer. That is to say, the annular metal layer of the chip structure is formed on a part of the surface of the bonding pad in the opening, and the UBM layer is disposed on the annular metal layer but not covered on the passivation layer.

In an embodiment of the present invention, the material of the annular metal layer comprises, for example, Al or Ti.

In the present invention, a metal layer is formed between the bonding pad and the UBM layer, such that the density of the current is reduced under the influence of the thickness of the metal layer when the current flows through the bonding pad and turns to the metal layer above the bonding pad. Therefore, the metal atoms of the UBM layer will not be lost due to electromigration.

In order to make the aforementioned and other objects, features and advantages of the present invention comprehensible, preferred embodiments accompanied with figures are described in detail below.

### BRIEF DESCRIPTION OF THE DRAWINGS

FIG. 1 is a schematic sectional view of a conventional chip structure.

FIGS. 2A to FIG. 2G are flow charts of the chip manufacturing process according to an embodiment of the present invention.

FIG. 3 is a schematic view of the chip structure according to another embodiment of the present invention.

### DESCRIPTION OF EMBODIMENTS

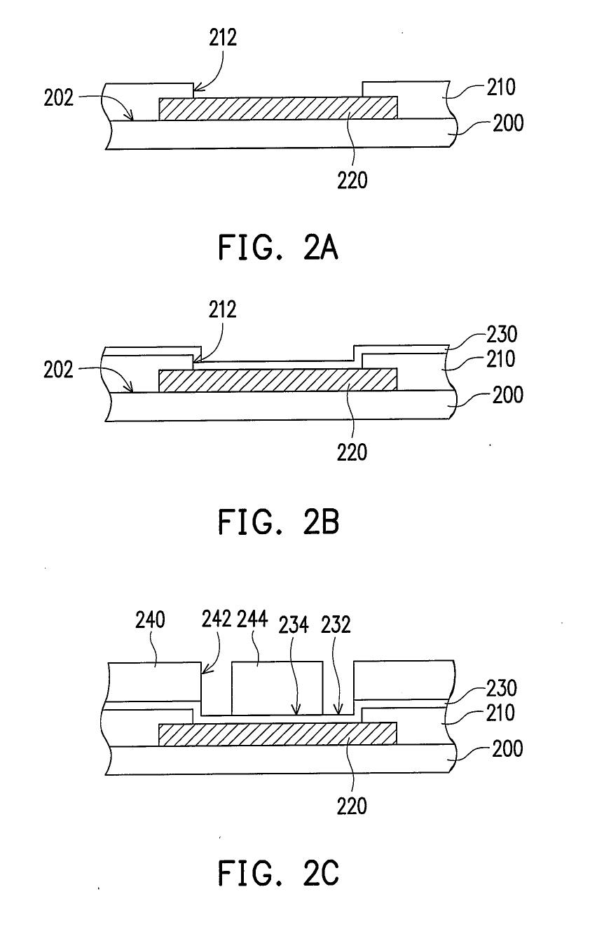

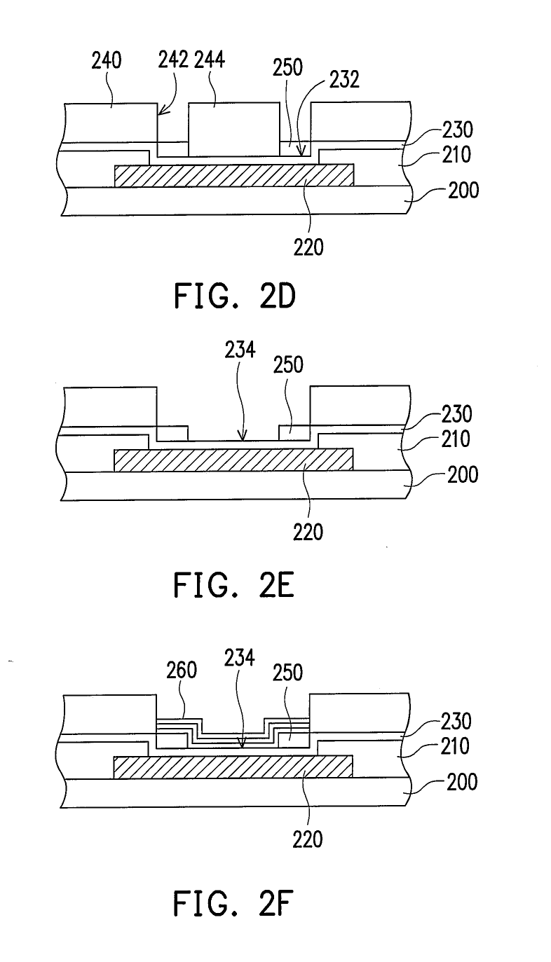

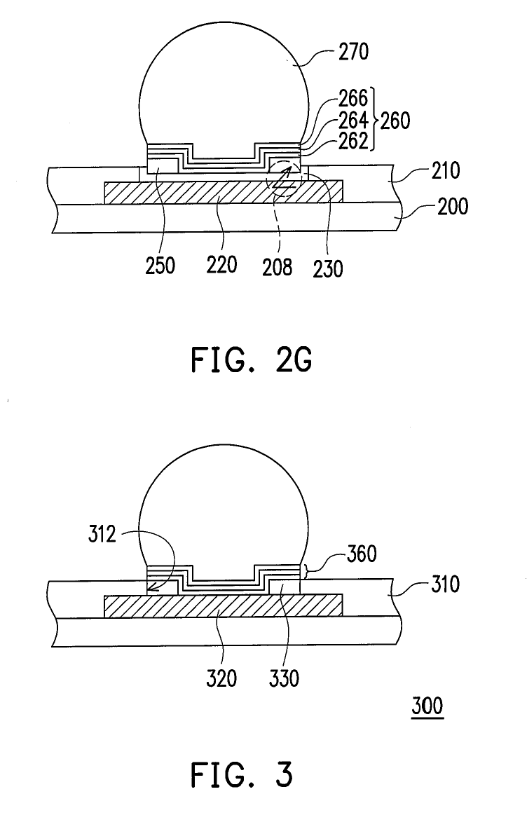

FIGS. 2A to FIG. 2G are flow charts of the chip manufacturing process according to an embodiment of the present invention. The chip manufacturing process includes the following steps. First, as shown in FIG. 2A, a wafer 200 comprising a passivation layer 210 and a plurality of bonding pads 220 (only one is shown in FIG. 2A) formed thereon is provided, wherein the bonding pads 220 are disposed on an active surface 202 of the wafer 200, and the passivation layer 210 is covered on the active surface 202. In addition, upper surfaces of the bonding pads 220 are exposed to a first opening 212 of the passivation layer 210.

Next, as shown in FIG. 2B, a first metal layer 230 is formed on the bonding pads 220 exposed by the first opening 212 and on the passivation layer 210. The first metal layer 230 is formed on the bonding pads 220 and the passivation layer 210 by, for example, a sputtering or evaporation process. In this embodiment, in order to achieve a good bonding between the first metal layer 230 and the bonding pads 220, the material of the first metal layer 230 may be the same as that of the bonding pads 220 or a metal of favorable bonding, for example, Al or Ti, and the material of the bonding pads 220 may be Al or Cu. Next, as shown in FIG. 2C, a photoresist 240 is formed on the first metal layer 230. The photoresist 240 of this embodiment has a second opening 242, and a photoresist block 244 defined by exposure and development of the photoresist 240 is disposed in the second opening 242. In addition, the first metal layer 230 corresponding to the second opening 242 has a first surface 232, and the first metal layer 230 corresponding to the photoresist block 244 has a second surface 234.

After forming the photoresist 240 on the first metal layer 230, a second metal layer 250 is then formed on the first surface 232 (as shown in FIG. 2D), wherein the second metal layer 250 is, for example, an annular structure. That is to say, the second metal layer 250 is only disposed on a part of the surface of the first metal layer 230. In addition, in order to achieve a favorable bonding between the first metal layer 230 and the second metal layer 250, the material of the first metal layer 230 may be the same as that of the second metal layer 250. In this embodiment, the material of the second metal layer 250 is, for example, Al or Ti, and the second metal layer 250 is formed on the first surface 232 by, for example, electroplating manufacturing process. Next, as shown in FIG. 2E, the photoresist block 244 is removed to expose the second surface 234. Next, as shown in FIG. 2F, a UBM layer 260 is formed on the surface of the second metal layer 250 and the second surface 234 of the first metal layer 230, wherein the UBM layer 260 is not covered above the passivation layer 210. The material of the UBM layer 260 is, for example, one selected from a group consisting of Ni, Cu, Ti, and an alloy thereof. For example, the UBM layer 260 may be a multilayer structure of Ti/Ni—V alloy/Cu, Ti—W alloy/Ni—V alloy/Cu, Ti/Ni—V alloy/Cu, or Ti—W alloy/Ni—V alloy/Cu.

Next, as shown in FIG. 2G, a conductive bump 270 is formed on the UBM layer 260, wherein the material of the conductive bump is, for example, Sn or Au. In this embodiment, for example, the photoresist 240 is removed before forming the conductive bump 270 on the UBM layer 260 (as shown in FIG. 2D), and then the conductive bump 270 is formed on the UBM layer 260 by printing. The conductive bump 270 can also be formed on the UBM layer 260 by using, for example, an electroplating process. Next, the photoresist 240 is removed. In addition, in this embodiment, the first metal layer 230 exposed outside the conductive bump 270 is removed by using the bump 270 as a mask. The formation of the conductive bump 270 is only used as an example, and is not intended to limit the present invention.

Referring to FIG. 2G, the UBM layer 260 of this embodiment includes, for example, an adhesion layer 262, a wetting layer 266 and a barrier layer 264. The adhesion layer 262 can enhance the bonding between the UBM layer 260 and the first metal layer 230/second metal layer 250, and the wetting layer 266 may increase the adhesion between the conductive bump 270 and the UBM layer 260. Moreover, the barrier layer 264 is used to avoid the diffusion reaction between materials of the bonding pads 220 and the conductive bump 270. The composite structure of the UBM layer 260 is only used as an example, and is not intended to limit the present invention.

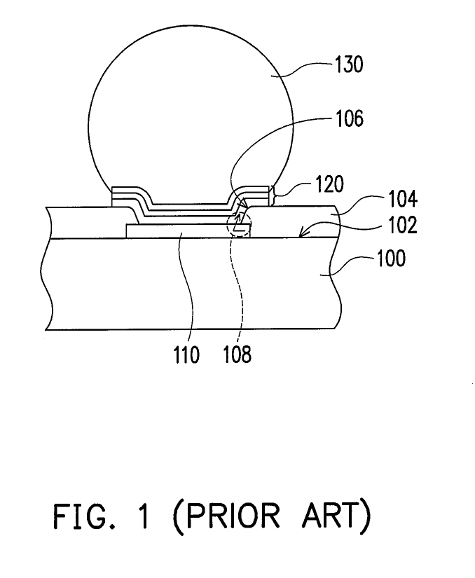

After the completion of the above chip manufacturing process, the wafer is sawed to obtain a plurality of chip structures (as shown in FIG. 2G). The chip structure may increase the distance between the bonding pads 220 and the UBM layer 260 through the first metal layer 230 and the second metal layer 250. Therefore, when the operating speed of the chip structure increases such that a large amount of current flows through the bonding pads 220 and flows to the UBM layer 260 at a turning angle 208 larger than or equal to 90 degrees, as the second metal layer 250 of annular structure is disposed at the turning angle 208, the current density will be gradually reduced, and the metal atoms of the UBM layer 260 will not be lost due to electromigration, thereby reducing or eliminating the open circuit problem caused by electromigration between the bonding pad 110 and the UBM layer 120 of the convention chip structure(as shown in FIG. 1). Therefore, the chip structure has a longer lifetime.

FIG. 3 is a schematic view of the chip structure according to another embodiment of the present invention. Referring to FIG. 3, the chip structure 300 of this embodiment is similar to the chip structure manufactured by the above chip manufacturing process, except that the chip structure 300 of this embodiment uses an annular metal layer 330 to replace the first metal layer 230 and the second metal layer 250 of the above chip structure 200. That is to say, the annular metal layer 330 of the chip structure 300 of this embodiment is formed on a part of the surface of the bonding pads 320 in the opening 312, and the UBM layer 360 is disposed on the annular metal layer 330 but not covered on the passivation layer 310.

Similarly, the chip structure 300 of this embodiment also increases the distance between the bonding pads 320 and the UBM layer 360 through the annular metal layer 330, such that the current density is gradually reduced after the current flows from the bonding pads 320 through the annular metal layer 330, so as to avoid electromigration phenomenon in the UBM layer 360.

In view of the above, in the present invention, a metal layer is formed between the bonding pads and the UBM layer to increase the distance between the bonding pads and the UBM layer. Therefore, regardless of the operating speed or operation time of the chip structure, as the current flows through the bonding pads and turns to the metal layer above the bonding pads, the density of the current will be reduced under the influence of the thickness of the metal layer, such that the metal atoms of the UBM layer will not be easily lost due to electromigration. In other words, the open circuit problem between the bonding pads and the UBM layer caused by electromigration as in the case of the conventional chip structure can be reduced or eliminated, and thus the chip structure of the present invention has a longer lifetime.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip structure, comprising:
a chip, having an active surface;
at least one bonding pad, disposed on the active surface;
a passivation layer, covering the active surface and having an opening exposing an upper surface of the bonding pad;
a metal layer, formed on the bonding pad in the opening;
a UBM layer, disposed on the metal layer and not covering the passivation layer; and
a conductive bump, formed on the UBM layer.

2. The chip structure as claimed in claim 1, wherein the metal layer comprises a first metal layer and a second metal layer, the first metal layer is disposed on the bonding pad, and the second metal layer is an annular structure and is disposed on a part of the surface of the first metal layer.

3. The chip structure as claimed in claim 2, wherein the first metal layer and the bonding pad are of the same material.

4. The chip structure as claimed in claim 2, wherein a material of the first metal layer and the second metal layer comprises Al or Ti.

5. The chip structure as claimed in claim 1, wherein a material of the UBM layer is one selected from a group consisting of Ni, Cu, Ti, and an alloy thereof.

6. The chip structure as claimed in claim 1, wherein a material of the conductive bump comprises Sn or Au.

7. A chip structure, comprising:
a chip, having an active surface;
at least one bonding pad, disposed on the active surface;
a passivation layer, covering the active surface and having an opening exposing an upper surface of the bonding pad;
an annular metal layer, formed on a part of a surface of the bonding pad in the opening;
a UBM layer, disposed on the annular metal layer and not covering the passivation layer; and
a conductive bump, formed on the UBM layer.

8. The chip structure as claimed in claim 7, wherein a material of the annular metal layer comprises Al or Ti.

9. The chip structure as claimed in claim 7, wherein a material of the UBM layer is one selected from a group consisting of Ni, Cu, Ti, and an alloy thereof.

10. The chip structure as claimed in claim 7, wherein a material of the conductive bump comprises Sn or Au.
